(19) United States
(12) Patent Application Publication
(10) Pub. No.: US 2023/0311098 A1
(43) Pub. Date: Oct. 5, 2023

(54) THE FORMATION OF CATALYST PT NANODOTS BY PULSED/SEQUENTIAL CVD OR ATOMIC LAYER DEPOSITION

(71) Applicant: L'Air Liquide, Société Anonyme pour I'Etude et I'Exploitation des Procédés Georges Claude, Paris (FR)

(72) Inventors: Takashi ONO, Yokosuka (JP); Takashi TERAMOTO, Yokosuka (JP); Christian DUSSARRAT, Tokyo (JP); Nicolas BLASCO, Grenoble (FR); Quentin DEMARLY, Léry (FR)

(21) Appl. No.: 18/023,785

(22) PCT Filed: Aug. 31, 2021
(86) PCT No.: PCT/US2021/048328

§ 371 Date: Feb. 28, 2023

Related U.S. Application Data
(60) Provisional application No. 63/072,562, filed on Aug. 31, 2020.

(51) Int. Cl. B01J 23/42; B01J 37/14; B01J 35/00; B01J 37/02; B01J 37/18; C23C 16/14; B01J 21/18; C23C 16/455; C23C 16/44

(52) U.S. Cl. CPC B01J 23/42; B01J 21/18; B01J 35/0013; B01J 35/006; B01J 35/0066; B01J 37/0228; B01J 37/14; B01J 37/18; C23C 16/14; C23C 16/4417; C23C 16/45553; C23C 16/45555

(57) ABSTRACT

The disclosure describes a method of depositing a plurality Ft metal containing nanodots on a catalyst carbon support structure by forming a vapor of Pt(PF3)4, exposing a surface of the catalyst support to the vapor of Pt(PF3)4, purging the surface of the catalyst support with a purge gas to remove the vapor of Pt(PF3)4, exposing the surface of the catalyst support to a second reactant in gaseous form, purging the surface of the catalyst support with a purge gas to remove the second reactant, and repeating these steps to form a plurality of the Pt metal containing nanodots.

### CROSS REFERENCE TO RELATED APPLICATIONS

This application claims priority to U.S. Provisional Pat. Application No. 63/072,562, filed Aug. 31, 2020, the entire contents of which are incorporated herein by reference.

### TECHNICAL FIELD

The formation of catalyst Pt nanodots by pulsed/sequential CVD or atomic layer deposition.

### BACKGROUND OF THE INVENTION

The state of the art is summarized in Van Bui, H., F. Grillo, and J. R. Van Ommen. “Atomic and molecular layer deposition: off the beaten track.” Chemical Communications 53.1 (2017): 45-71 (reference numbers omitted):

ALD of Pt. The development of Pt ALD started in 2003 with the seminal work of Aaltonen et al., who demonstrated the thermal ALD of Pt thin films using methylcyclopentadienyl-(trimethyl) platinum (MeCpPbMe₃) as the Pt precursor and O2 as the co-reactant. To date, this is still the most commonly used ALD process for growing both thin films and NPs of Pt on a wide range of substrates such as flat surfaces, nanowires, nanoparticles, and carbon nanomaterials. Given the potential applications of Pt ALD, several research groups have conducted fundamental studies aimed at elucidating the surface chemistry behind the formation of metallic Pt. These studies suggest that the surface chemistry relies on oxidation reactions in both the MeCpPtMe₃ and the O2 exposures. The chemisorption of MeCpPtMe₃ is believed to take place via partial oxidation of the organic ligands by active oxygen adsorbed on the substrate surface. Such reaction would then reach saturation upon consumption of the available active surface oxygen. The role of the oxidation step via 02 is thus twofold: oxidizing the remaining ligands and restoring the layer of adsorbed oxygen, which is necessary for the subsequent MeCpPtMe₃ chemisorption. The studies also indicated that oxygen dissociates on the platinum surface forming a persisting layer of monoatomic oxygen which is particularly active towards the combustion of the organic ligands of MeCpPtMe₃. The ALD window usually reported for such surface chemistry is 200-350° C. In particular, 200° C. has been widely accepted as the lower temperature limit, although very recently growth at a slightly lower temperature (i.e., 175° C.) has been obtained. Such lower limit has been ascribed to the low reactivity of oxygen towards ligand combustion at temperature below 200° C. Such high deposition temperatures make the thermal process unsuitable for heat-sensitive substrates. Furthermore, when used for the deposition of NPs, high temperatures are not desirable as they can promote sintering and thus limit the ability to control the NP size. In order to circumvent this limitation the use of plasma and ozone has been explored. However, plasma processes are mainly suitable for the deposition of Pt thin films and NPs on flat substrates, and their applications on substrates with complex geometries such as powders are still limited.

As discussed in the above review article, the state of the art means of plasma enhanced deposition has not so far been successfully deployed to lower deposition temperatures on cathode carbon supports used for catalyst Pt nanodots. To date, the art is still lacking in a Pt deposition solution for cathode carbon supports that enables adequate nanodot formation, without excessive Pt oxide formation, to meet the practical requirements for fuel cells for vehicles, specifically those using a polymer electrolyte membrane design.

### BRIEF SUMMARY OF THE INVENTION

The Invention may be understood in relation to the following non-limiting, exemplary embodiments described as enumerated sentences:
1. A method of depositing Pt metal containing nanodots on a catalyst support structure, preferably a catalyst carbon support structure, the method comprising the steps of:
   a. Forming a vapor of Pt(PF₃)₄,
   b. Exposing a surface of the catalyst support structure to the vapor of Pt(PF₃)₄,
   c. Purging the surface of the catalyst support structure with a purge gas to remove the vapor of Pt(PF₃)₄,
   d. Exposing the surface of the catalyst structure to a second reactant in gaseous form,
   e. Purging the surface of the catalyst support structure with a purge gas to remove the second reactant,
   f. Repeating steps a. - e. to form a plurality of the Pt metal containing nanodots on the catalyst support structure,
   wherein the temperature of the catalyst support structure during step a. and/or step b. is from 50° C. to 300° C., preferably from 100° C. to less than 200° C., more preferably 100° C. to 175° C. or to less than 175° C., such as 100° C. or 150° C.
2. The method of SENTENCE 1, wherein the second reactant comprises an oxidizing agent selected from the group consisting of H₂O, O₂, O₃, oxygen radicals and mixtures thereof; preferably O₂.
3. The method of SENTENCE 1, wherein the second reactant comprises a reducing agent selected from the group consisting of H₂, NH₃, SiH₄, Si₂H₆, Si₃H₈, SiH₂Me₂, SiH₂Et₂, N(SiH₃)₃, hydrogen radicals, hydrazine, a methylhydrazine, amines and mixtures thereof; preferably H₂.
4. The method of SENTENCE 1, wherein the second reactant is selected from the group consisting of H₂, O₂, and combinations thereof.
5. The method of any of SENTENCEs 1 - 4, wherein the repetition of steps a.-e. is from 5 - 20 times.
6. The method of any of SENTENCEs 1 - 5, wherein the plurality of the Pt metal containing nanodots are formed by an atomic layer deposition reaction.
7. The method of any of SENTENCEs 1-6, wherein the largest linear dimension of the nanodots has a range from 0.25 nm to 15 nm and/or a mean of 2 nm - 7 nm.
8. The method of any of SENTENCEs 1-7, wherein the catalyst support structure comprises multiple discrete particles having an outer surface and these discrete particles have a coverage of the Pt metal containing nanodots which is at least an average of 1 nanodot per nm² of the particle surface area after step f.
9. The method of any of SENTENCEs 1-8, wherein each nanodot comprises sufficient Pt so that a) the atomic percentage of Pt for the catalyst support structure with the plurality of the Pt containing nanodots is from 0.5% to 3%, preferably 1% to 2% and/or b) the weight percentage of Pt is from 5% to 50%, preferably 10% to 30%.
10. The method of any of SENTENCEs 1-9, wherein the catalyst support structure is a catalyst carbon support structure.
11. The method of SENTENCE 10, wherein the plurality of Pt nanodots are formed directly on a carbon component of the catalyst carbon support.
12. The method of SENTENCEs 10 or 11, wherein the catalyst carbon support structure is a single wall fullerene such as C₆₀ and C₇₂, multiwall fullerenes, single wall or multiwall nanotubes, nanohorns, and/or has a density of about 0.2 g/cm3 to about 1.9 g/cm3 such as specialty carbons like VULCAN or Imerys’ SUPER C65.
13. The method of any of SENTENCEs 1-12, further comprising a step of exposing the surface of the catalyst structure to a third reactant in gaseous form, wherein, if the second reactant is an oxidizing agent, the third reactant is a reducing agent, and vice versa.
14. The method of SENTENCE 13, wherein the step of exposing the surface of the catalyst structure to the third reactant, is separated from step d. by step e.
15. The method of SENTENCE 14, wherein the second reactant is oxygen and the third reactant is hydrogen.
16. A method of depositing Pt metal containing nanodots on a catalyst support structure, preferably a catalyst carbon support structure, the method comprising the steps of:
   a. Forming a vapor of Pt(PF₃)₄,
   b. Exposing a surface of the catalyst support structure to the vapor of Pt(PF₃)₄,
   wherein step b. is for a time sufficient to form a plurality of the Pt metal containing nanodots on the catalyst support structure,
   wherein the catalyst support structure is not exposed to any additional reactants to form the plurality of the Pt metal containing nanodots on the catalyst support structure, and
   wherein the temperature of the catalyst support structure surface during step a. and/or step b. is from 50° C. to 300° C., preferably from 100° C. to less than 200° C., more preferably 100° C. to 175° C. or to less than 175° C., such as 100° C. or 150° C.
17. The method of SENTENCE 16, wherein the largest linear dimension of the nanodots has a range from 0.25 nm to 15 nm and/or a mean of 2 nm - 7 nm.
18. The method of SENTENCE 16 or 17, wherein the catalyst support structure comprises multiple discrete particles having an outer surface and these discrete particles have a coverage of the Pt metal containing nanodots which is at least an average of 1 nanodot per nm² of the particle surface area after step b.
19. The method of any of SENTENCEs 16-18, wherein each nanodot comprises sufficient Pt so that a) the atomic percentage of Pt for the catalyst support structure with the plurality of the Pt containing nanodots is from 0.5% to 3%, preferably 1% to 2% and/or b) the weight percentage of Pt is from 5% to 40%, preferably 10% to 30%.
20. The method of any of SENTENCEs 16-19, wherein the catalyst support structure is a catalyst carbon support structure.
21. The method of SENTENCE 20, wherein the plurality of Pt nanodots are formed directly on a carbon component of the catalyst carbon support.
22. The method of SENTENCE 20 or 21, wherein the catalyst carbon support structure is a single wall fullerene such as C₆₀ and C₇₂, multiwall fullerenes, single wall or multiwall nanotubes, nanohorns, and/or has a density of about 0.2 g/cm3 to about 1.9 g/cm3 such as specialty carbons like such as VULCAN or Imerys’ SUPER C65.
23. A method of depositing Pt metal containing nanodots on a catalyst support structure, preferably a catalyst carbon support structure, the method comprising the steps of:
   a. Forming a vapor of Pt(PF₃)₄,
   b. Exposing a surface of the catalyst support structure to the vapor of Pt(PF₃)₄ and an oxidizing agent, concurrently,
   wherein step b. is for a time sufficient to form a plurality of the Pt metal containing nanodots on the catalyst support structure,
   wherein the catalyst support structure is not exposed to any additional reactants to form the plurality of the Pt metal containing nanodots on the catalyst support structure, and
   wherein the temperature of the catalyst support structure surface during step a. and/or step b. is from 50° C. to 300° C., preferably from 100° C. to less than 200° C., more preferably 100° C. to 175° C. or to less than 175° C., such as 100° C. or 150° C.
24. The method of SENTENCE 23, wherein the oxidizing agent is selected from the group consisting of H₂O, O₂, O₃, oxygen radicals and mixtures thereof; preferably O₂.
25. The method of SENTENCE 23 or 24, wherein the largest linear dimension of the nanodots has a range from 0.25 nm to 15 nm and/or a mean of 2 nm - 7 nm.
26. The method of any of SENTENCEs 23-25, wherein the catalyst support structure comprises multiple discrete particles having an outer surface and these discrete particles have a coverage of the Pt metal containing nanodots which is at least an average of 1 nanodot per nm² of the particle surface area after step b.
27. The method of any of SENTENCEs 23-26, wherein each nanodot comprises sufficient Pt so that a) the atomic percentage of Pt for the catalyst support structure with the plurality of the Pt containing nanodots is from 0.5% to 3%, preferably 1% to 2% and/or b) the weight percentage of Pt is from 5% to 40%, preferably 10% to 30%.
28. The method of any of SENTENCEs 23-27, wherein the catalyst support structure is a catalyst carbon support structure.
29. The method of SENTENCE 28, wherein the plurality of Pt nanodots are formed directly on a carbon component of the catalyst carbon support
30. The method of SENTENCE 28 or 29, wherein the catalyst carbon support structure is a single wall fullerene such as C₆₀ and C₇₂, multiwall fullerenes, single wall or multiwall nanotubes, nanohorns, and/or has a density of about 0.2 g/cm3 to about 1.9 g/cm3 such as specialty carbons like such as VULCAN or Imerys’ SUPER C65.
31. The method of any of the preceding SENTENCEs, wherein the plurality of Pt nanodots comprise face-centered cubic Pt crystals.
32. The method of any of the preceding SENTENCEs, wherein the Utilization Efficiency is from 30 weight percent to99 weight percent, preferably at least 50 weight percent, more preferably at least 75 weight percent, such as 50 weight percent to 90 weight percent or 75 weight percent to 80 weight percent.

### BRIEF DESCRIPTION OF THE SEVERAL VIEWS OF THE DRAWING

FIG. 1 shows the vapor pressure vs. temperature for MeCpPtMe₃ (lower line) and Pt(PF₃)₄ (upper line);

FIG. 2 shows the powder vapor deposition device used to expose C65 powder to Pt(PF₃)₄ in the experiments described herein;

FIG. 3 shows Pt nanodot deposition on C65 by CVD with Hydrogen as the co-reactant (replicating the prior art). XPS data is presented as X-axis = Normalized Intensity (a.u.) and Y-axis = eV;

FIG. 4 shows Pt nanodot deposition on C65 by ALD with Hydrogen as the co-reactant. XPS data is presented as X-axis = Normalized Intensity (a.u.) and Y-axis = eV. The vertical lines demark the eV’s for Pt⁰. The most Pt was deposited at 100° C. and the most Pt⁰ was deposited at 150° C.;

FIG. 5 shows scanning electron microscopy (SEM) images of C65 from the experiments of FIG. 4 for the 100 degree C deposition;

FIG. 6 shows representative results from a thermal decomposition deposition without Hydrogen. XPS data is presented as X-axis = Normalized Intensity (a.u.) and Y-axis = eV. The vertical lines demark the eV’s for Pt⁰. The amount of Pt nanodots increased with each temperature increase. However the Pt was almost entirely oxidized at all temperatures;

FIG. 7 shows representative results for Oxygen CVD. XPS data is presented as X-axis = Normalized Intensity (a.u.) and Y-axis = eV. The vertical lines demark the eV’s for Pt⁰. Pt nanodot deposition increased with temperature to 150° C. and then decreased at 200° C. to about the level of the 100° C. reaction. All conditions had substantial amounts of oxidized Pt, but the 150 degree C deposition produced the most Pt⁰;

FIG. 8 shows oxygen as a coreactant in sequential exposures (e.g. ALD), produced more Pt nanodots on the C65. XPS data is presented as X-axis = Normalized Intensity (a.u.) and Y-axis = eV. The vertical lines demarc the eV’s for Pt⁰. Both the amount of Pt, and the portion thereof in the form of Pt⁰, increased with temperature from 50° C. to 150° C. with 200° C. having comparable results as 150° C.;

FIG. 9 shows scanning electron microscopy (SEM) images of C65 from the experiments of FIG. 8 for the 100 degree C deposition.

### DETAILED DESCRIPTION OF THE INVENTION

“Nanodot” means a discrete deposit of e.g. Pt having a maximal cross-sectional dimension from 1 nanometer to 100 nanometers. Nano dots are most often roughly hemispherical or roughly circular, but may be any shape, including irregular shaped formations.

“Catalyst support structure” means materials used for supporting catalytic materials such as Pt nanodots in the cathodes of lithium ion batteries. See, e.g., Ye, Siyu, Miho Hall, and Ping He. “PEM fuel cell catalysts: the importance of catalyst support” ECS Transactions 16.2 (2008): 2101; Shao, Yuyan, et al. “Novel catalyst support materials for PEM fuel cells: current status and future prospects.” Journal of Materials Chemistry 19.1 (2009): 46-59.

“Catalyst carbon support structure” means a catalyst support structure having carbon as a component. Examples include carbon black, graphite, graphene, C₆₀ (“buckyballs”, “fullerenes”), C₇₂ (Ma, Jian-Li, et al. “C₇₂: A novel low energy and direct band gap carbon phase.” Physics Letters A (2020): 126325), carbon walled nanotubes (including multi walled nanotubes), carbon nanofibers and silicon-mesoporous carbon composites such as C65.

“C65” means a catalyst carbon support structure having a silicon-mesoporous carbon composite such as those described in Spahr, Michael E., et al. “Development of carbon conductive additives for advanced lithium ion batteries.” Journal of Power Sources 196.7 (2011): 3404-3413.

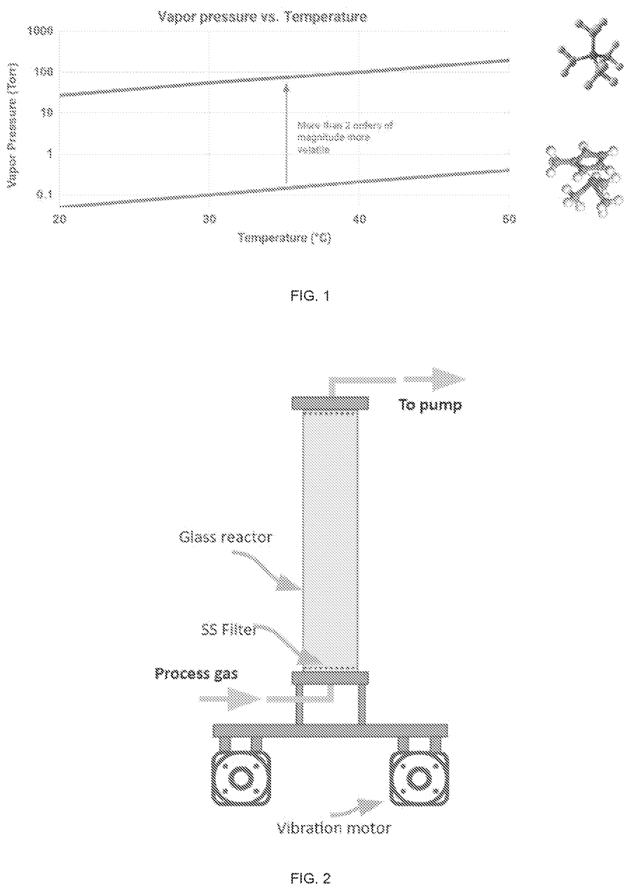

Tetrakis(trifluorophosphine)platinum (Pt(PF₃)₄) is a known chemical (CAS#19529-53-4). As shown in FIG. 1, Pt(PF₃)₄ has a much higher vapor pressure than the current Platinum deposition precursor Pt(MeCp)Me₃.

Previous work with Pt(PF₃)₄ described its use as a CVD precursor for thin film depositions. Rand, Myron J. “Chemical Vapor Deposition of Thin- Film Platinum.” Journal of The Electrochemical Society 120.5 (1973): 686-693. The previous work focused on thermal CVD for Pt thin film deposition. The operable temperature range was determined to be greater than 175° C., and specifically 200° C. to 300° C. to form metallic Pt as the predominant Pt component of the film. Lower temperatures resulted in incomplete pyrolysis and poor quality films. Oxidizing environments were avoided and even Nitrogen had a negative effect on film quality.

We repeated and verified the foregoing. H₂ CVD at 50, 100, 150 and even 200° C. yielded negligible Pt nanodot formation on a C65 substrate (discussed in the experimental section below). The small amount of Pt deposited was mostly oxidized. The prior art and our own results thus indicated that Pt(PF₃)₄ was not a candidate for low temperature Pt nanodot deposition. Thus our subsequent work, demonstrating successful deposition conditions was therefore highly unexpected and surprising.

### General Conditions for Pt Nanodot Depositions With Pt(PF₃)₄

The target substrate for Pt nanodot deposition was conductive carbon blacks C-NERGY™ Super C65. Spahr, Michael E., et al. “Development of carbon conductive additives for advanced lithium ion batteries.” Journal of Power Sources 196.7 (2011): 3404-3413.

The depositions were performed in a laboratory scale powder deposition shown in FIG. 2. Unless otherwise noted, all Pt nanodot depositions were performed under the following conditions:
Pt precursor (supplied by MFC)
Pt(PF₃)₄ Flow rate : ~0.56 sccm actual (2 sccm as N₂ MFC)
Canister T: 30° C.
Canister P: VP of PPF
Co-reactant O2 or H2 Flow rate: 10 sccm
Push N₂ 35 sccm
Reactor Pressure : 10 Torr
Loaded substrate (carbon support): C-NERGY super C65 : 1 gram (8 mm stainless steel ball is loaded with carbon powder to prevent agglomeration).

XRD and XPS reference data were collected from pristine C65, Pt metal foil, and C65 + Pt metal mesh. At 100° C., 150° C., 175° C., 200° C., a XRD pattern corresponding to Pt pattern and C pattern was observed, showing that metal platinum can be formed in such conditions. From the reference materials, XPS Pt4f_{7/2} peak position was 71.2 eV (corresponding to Pt⁰) and C1’s peak position is 284.6 eV. XPS data is presented as X-axis = Normalized Intensity (a.u.) and Y-axis = eV.

### Comparative Example: Pt(PF₃)₄ CVD with Hydrogen

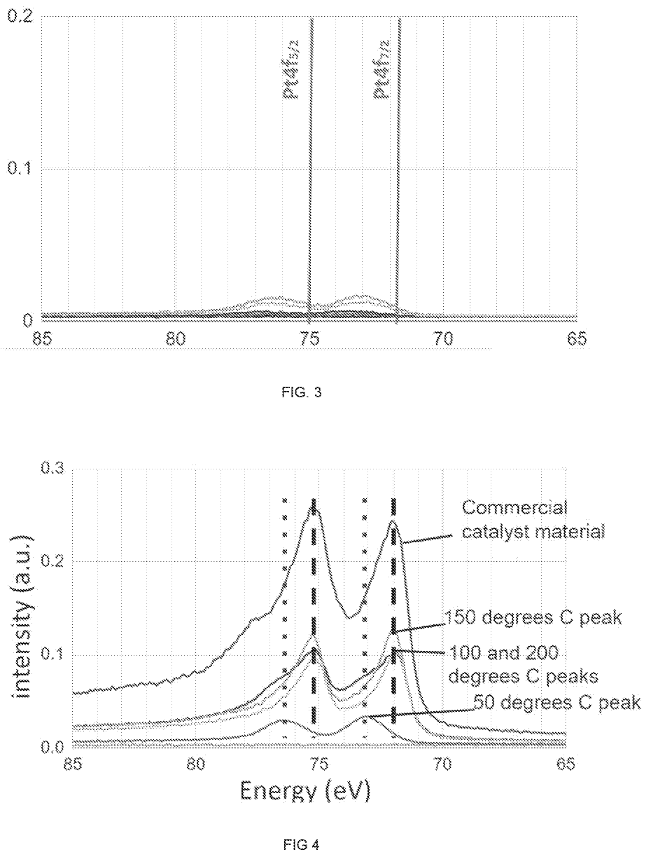

CVD was performed for 2400 seconds using the above conditions at 50, 100, 150 and 200° C. Representative XPS data is shown in FIG. 3. As expected based on the prior art, very little Pt deposited under these conditions, even at 200° C. (the highest amount for this series of experiments) and the resulting Pt was largely oxidized. The prior art deposition process was therefore confirmed to be also unsuitable for Pt nanodot deposition, in addition to thin film deposition, at 200 degrees or less.

### Pt(PF₃)₄ sequential deposition or atomic layer deposition with Hydrogen

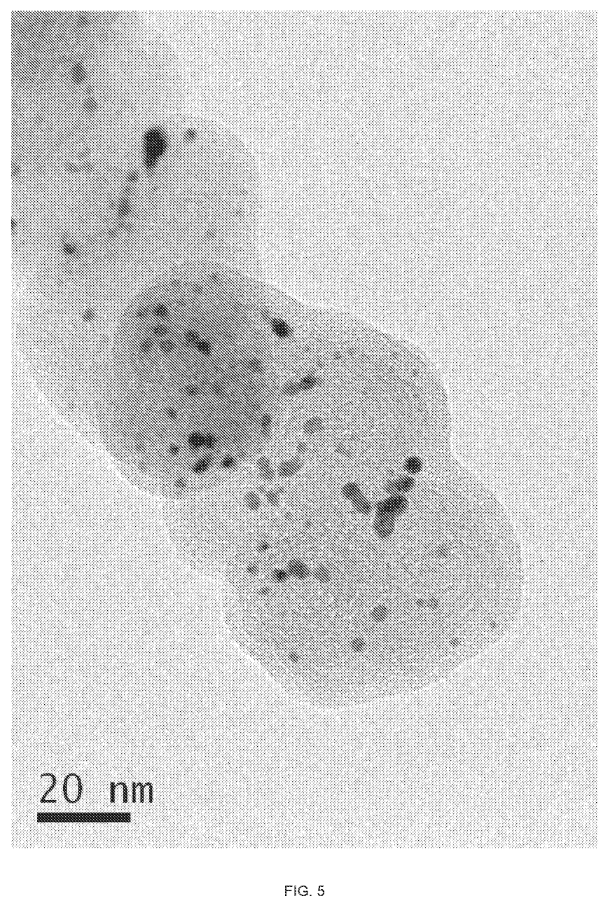

In direct contrast to the CVD results, alternating Pt(PF₃)₄ and Hydrogen delivery, into separated substrate exposure steps (such as an atomic layer deposition process), produced dramatically different and surprising results. Representative results from an ALD deposition with Hydrogen are shown in FIG. 4. (Number of ALD cycles: 12 ; ALD sequence: PPF 200s ; Purge 600s ; H₂ 500s ; Purge 600s; 100, 150 and 200° C.). Compared to FIG. 3, there is a clear and dramatic improvement in Pt deposition, and this was sufficient to be viable for Pt Nanodot deposition. The majority of Pt was metallic (identified by the vertical - - - - line) rather than oxidized (identified by the - line) which is also preferred for catalytic materials. FIG. 5 shows scanning electron microscopy (SEM) images of C65 from FIG. 4 for the 150 degree C deposition. Of note, the quantity of Pt deposited actually goes down at 200° C., indicating that the optimal temperature for Pt nanodot deposition is > 100° C. to < 200° C., contrary to the prior art’s conclusions for Pt thin film depositions. This result and the Oxygen deposition results show that there is, unexpectedly, no meaningful correlation between the prior art Pt thin film depositions and Pt nanodot depositions on catalyst support structures or materials.

For the aforedescribed deposited Pt nanodots, we performed additional analysis, specifically powder X-ray Diffraction, Differential Thermal analysis and Thermogravimetric analysis in air. The XRD results indicate that the metallic Pt deposited at 150° C. is crystalline, having an face-centered cubic (FCC) structure. FCC crystalized Pt (rather than amorphous Pt) is the preferred form of metallic Pt for catalytic activity.

For industrialization, the amount of metallic Pt deposited onto a catalytic support and its stability are important considerations. TGA + DTA analysis showed that Pt nanodots formed at 150° C. were thermally stable up to approximately 575° C. Final residual mass at 1000° C. for the TGA showed that approximately 9 weight percent of the materials was deposited Pt. By varying the number of cycles, the pulse length and the temperature, 30 weight percent Pt (or higher) was achieved, with the best results at 150° C., of the temperatures tested.

Utilization Efficiency means the [The amount of Pt deposited on a catalytic support]/[the amount of Pt introduced as Pt(PF₃)₄] and can be expressed as a fraction or as a percentage. By varying the number of cycles, the pulse length and the temperature, 75% (or higher) Pt Utilization Efficiency was achieved, with the best results at 150° C., of the temperatures tested.

### Pt(PF₃)₄ deposition without co-reactant (thermal decomposition)

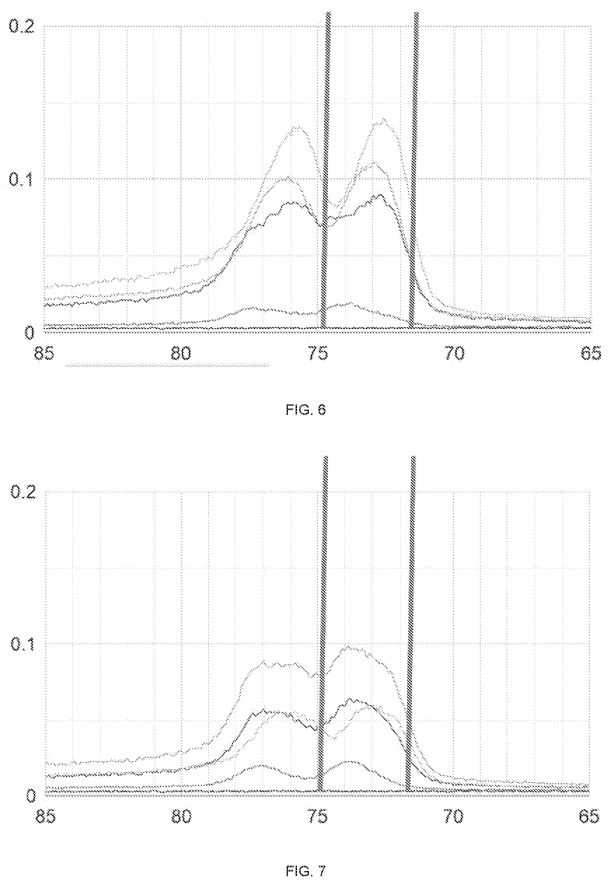

In view of the unexpected and counterintuitive results with alternating Pt(PF₃)₄ and Hydrogen delivery, we examined a purely thermal decomposition CVD process without any co-reactant (2400 seconds reaction time; 50, 100, 150 and 200° C.). Representative results from a thermal decomposition deposition without Hydrogen are shown in FIG. 6. SEM of C65 samples showed Pt nanodots similar to those seen in FIG. 5.

### Pt(PF₃)₄ : CVD deposition with Oxygen; sequential deposition or atomic layer deposition with Oxygen

In view of the unpredicted and unexpected Pt nanodot depositions seen without co-reactant and with alternating Hydrogen co-reactant, we explored use of Oxygen as a representative oxidizing co-reactant. Based on the prior art, Oxygen is not compatible with Pt film deposition using Pt(PF₃)₄. Replacing Hydrogen with Oxygen (but otherwise keeping the conditions the same), we determined that Oxygen is not only compatible with Pt nanodot deposition, but in some ways also better than Hydrogen.

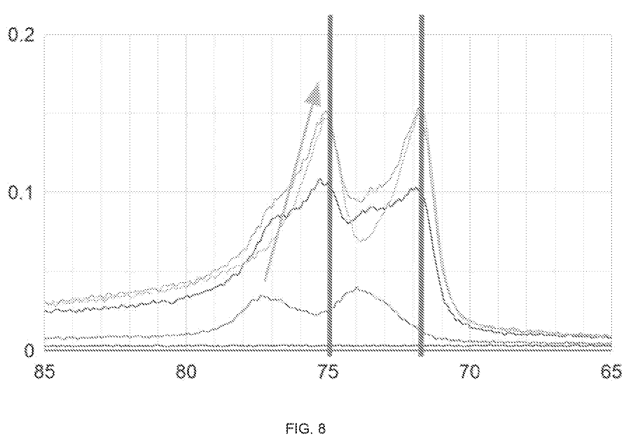

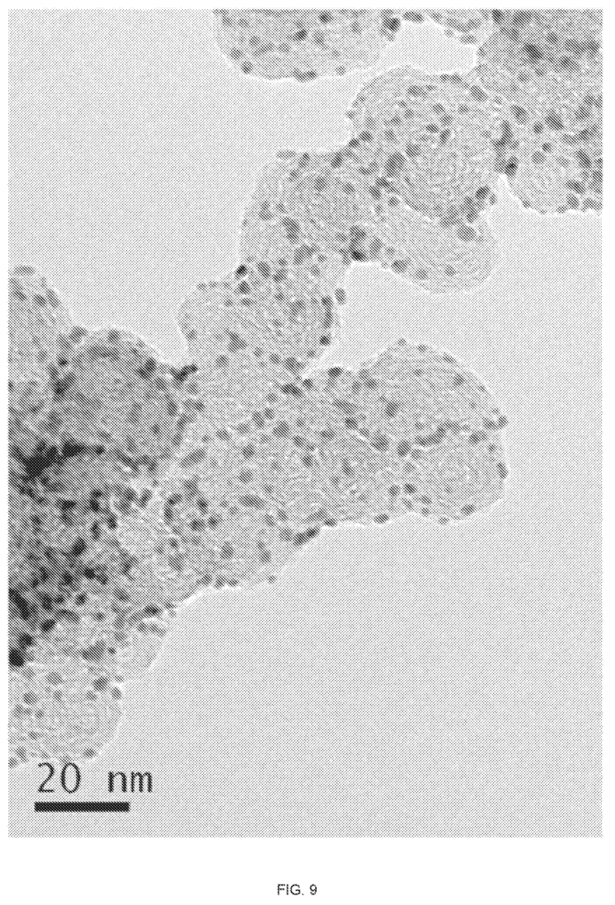

FIG. 7 shows representative results for Oxygen CVD. In contrast to the results with Hydrogen shown in FIG. 3, Oxygen co-reactant CVD produced substantially more Pt nanodot formation on the C65 (SEMs not shown). Likewise, Oxygen as a coreactant in sequential exposures (e.g. ALD), produced more Pt nanodots on the C65 (FIG. 8). A representative SEM of the Pt nanodots formed at 100° C. is shown in FIG. 9.

### Preferred Pt Nanodot Depositions

In contrast to the prior art Pt film depositions, Pt Nanodot depositions occur at temperatures below 200° C., preferably at or below 175° C., such as 150° C., 100° C., and even at 50° C. to a lesser extent. The industry need is especially for depositions of 175° C. or less based on the thermal tolerances of current catalyst substrate materials such as C65. While we demonstrate robust Pt nanodot deposition at low temperatures, the preferred Pt state is metallic Pt rather than oxidized Pt. Thus conditions that favor metallic Pt content in the Pt nanodots are preferred. Further parameter optimizations are expected to further improve these results. One exemplary optimization is the use of sequential Oxygen and then Hydrogen co-reactant depositions to produce a blended result of their relative benefits while mitigating their relative undesirable features. For example, Oxygen (or any oxidant) could be used for a majority of ALD cycles, followed by Hydrogen (or any other reducing agent) ALD cycles.

1. A method of depositing Pt containing nanodots on a catalyst support structure, preferably a catalyst carbon support structure, the method comprising the steps of:
a. forming a vapor of Pt(PF₃)₄,
b. exposing a surface of the catalyst support structure to the vapor of Pt(PF₃)₄,
c. purging the surface of the catalyst carbon support structure with a purge gas to remove the vapor of Pt(PF₃)₄,
d. exposing the surface of the catalyst carbon structure to a second reactant in gaseous form,
e. purging the surface of the catalyst carbon support structure with a purge gas to remove the second reactant,
f. repeating steps a. - e. to form a plurality of the Pt containing nanodots on the catalyst carbon support structure
wherein the temperature of the catalyst support structure during step a. and/or step b. is from 50° C. to 300° C.

2. The method of claim 1, wherein the second reactant comprises an oxidizing agent selected from the group consisting of H₂O, O₂, O₃, NO₂, oxygen radicals and mixtures thereof.

3. The method of claim 1, wherein the second reactant comprises a reducing agent selected from the group consisting of H₂, NH₃, SiH₄, Si₂H₆, Si₃H₈, SiH₂Me₂, SiH₂Et₂, N(SiH₃)₃, hydrogen radicals, hydrazine, methylhydrazine, amines, NO, N₂O, and mixtures thereof.

4. The method of claim 1, wherein the second reactant is selected from the group consisting of H₂, O₂, and combinations thereof.

5-6. (canceled)

7. The method of claim 1, wherein the largest linear dimension of the nanodots has a range from 0.25 nm to 15 nm and/or a mean of 2 nm - 7 nm.

8. (canceled)

9. The method of claim 1, wherein each Pt containing nanodot comprises sufficient Pt so that a) the atomic percentage of Pt for the catalyst carbon support structure with the plurality of the Pt containing nanodots is from 0.5% to 3% and/or b) the weight percentage of Pt is from 5% to 50%.

10. The method of claim 1, wherein the catalyst carbon support structure contains at least 30% Carbon by weight.

11. The method of claim 10, wherein the plurality of Pt nanodots are formed directly on a carbon component of the catalyst carbon support structure.

12. (canceled)

13. The method of claim 1, further comprising a step of exposing the surface of the catalyst carbon support structure to a third reactant in gaseous form, wherein, if the second reactant is an oxidizing agent, the third reactant is a reducing agent, and vice versa.

14. The method of claim 13, wherein the step of exposing the surface of the catalyst carbon support structure to the third reactant, is separated from step d. by step e.

15. The method of claim 14, wherein the second reactant is oxygen and the third reactant is hydrogen.

16. A method of depositing Pt containing nanodots on a catalyst support structure, preferably a catalyst carbon support structure, the method comprising the steps of:
a. Forming a vapor of Pt(PF₃)₄,
b. Exposing a surface of the catalyst support structure to the vapor of Pt(PF₃)₄, wherein step b. is for a time sufficient to form a plurality of the Pt containing nanodots on the catalyst support structure,
wherein the catalyst support structure is not exposed to any additional reactants to form the plurality of the Pt containing nanodots on the catalyst support structure, and
wherein the temperature of the catalyst support structure surface during step a. and/or step b. is from 50° C. to 300° C.

17. The method of claim 16, wherein the largest linear dimension of the nanodots has a range from 0.25 nm to 15 nm and/or a mean of 2 nm - 7 nm.

18. (canceled)

19. The method of claim 16, wherein each nanodot comprises sufficient Pt so that a) the atomic percentage of Pt for the catalyst support structure with the plurality of the Pt containing nanodots is from 0.5% to 3% and/or b) the weight percentage of Pt is from 5% to 50%.

20. The method of claim 16, wherein the catalyst support structure is a catalyst carbon support structure, preferably containing at least 30% Carbon by weight.

21. The method of claim 20, wherein the plurality of Pt containing nanodots are formed directly on a carbon component of the catalyst carbon support structure.

22. (canceled)

23. A method of depositing Pt containing nanodots on a catalyst support structure, preferably a catalyst carbon support structure, the method comprising the steps of:
a. forming a vapor of Pt(PF₃)₄,
b. exposing a surface of the catalyst support structure to the vapor of Pt(PF₃)₄ and an oxidizing agent, concurrently,
wherein step b. is for a time sufficient to form a plurality of the Pt containing nanodots on the catalyst support structure,
wherein the catalyst support structure is not exposed to any additional reactants to form the plurality of the Pt containing nanodots on the catalyst support structure, and
wherein the temperature of the catalyst support structure surface during step a. and/or step b. is from 50° C. to 300° C.

24. The method of claim 23, wherein the oxidizing agent is selected from the group consisting of H₂O, O₂, O₃, NO₂, oxygen radicals and mixtures thereof.

25. The method of claim 24, wherein the largest linear dimension of the nanodots has a range from 0.25 nm to 15 nm and/or a mean of 2 nm - 7 nm.

26. (canceled)

27. The method of claim 23, wherein each nanodot comprises sufficient Pt so that a) the atomic percentage of Pt for the catalyst support structure with the plurality of the Pt containing nanodots is from 0.5% to 3% and/or b) the weight percentage of Pt is from 5% to 50%.

28. The method of any of claim 23, wherein the catalyst support structure is a catalyst carbon support structure, preferably containing at least 30% Carbon by weight.

29. The method of claim 28, wherein the plurality of Pt containing nanodots are formed directly on a carbon component of the catalyst carbon support.

30-32. (canceled)
